(19) United States
(12) Patent Application Publication
(10) Pub. No.: US 2006/0231872 A1
(43) Pub. Date: Oct. 19, 2006

(54) Field effect transistor using insulator-semiconductor transition material layer as channel material and method of manufacturing the same

(76) Inventors: Hyun Tak Kim, Daejeon-city (KR); Kwang Yong Kang, Daejeon-city (KR); Doo Hyeb Youn, Daejeon-city (KR); Byung Gyu Chae, Daejeon-city (KR)

Correspondence Address: BLAKELY SOKOLOFF TAYLOR & ZAFMAN, 12400 WILSHIRE BOULEVARD, SEVENTH FLOOR, LOS ANGELES, CA, 90025-1030, US

(21) Appl. No.: 10/557,552

(22) PCT Filed: Dec. 30, 2003
(86) PCT No.: PCT/KR03/02893

§ 371 Date: Nov. 15, 2005

(51) Int. Cl. H01L 29/76

(52) U.S. Cl. 257/288

(57) ABSTRACT

Provided is a field effect transistor including an insulator-semiconductor transition material layer. The insulator-semiconductor transition material layer selectively provides a first state where charged holes are not introduced to a surface of the insulator-semiconductor transition material layer when a gate field is not applied and a second state where a large number of charged holes are introduced to the surface of the insulator-semiconductor transition material layer to form a conductive channel when a negative field is applied. A gate insulating layer is formed on the insulator-semiconductor transition material layer. A gate electrode is formed on the gate insulating layer to apply a negative field of a predetermined intensity to the insulator-semiconductor transition material layer. A source electrode and a drain electrode are disposed to face each other at both sides of the insulator-semiconductor transition material layer so that charge carriers can flow through the conductive channel while the insulator-semiconductor transition material layer is in the second state.

### TECHNICAL FIELD

The present invention relates to a field effect transistor and method of the same, and more particularly, to a field effect transistor using an insulator-semiconductor transition material layer as a channel material, and manufacture method of the same.

### BACKGROUND ART

Among transistors, metal oxide semiconductor field effect transistors (MOSFETs) have currently become the leading choice of designers as ultra-small size and high speed switching transistors. MOSFETs employ a double pn-junction structure as a base structure, the pn-junction structure having a linear property at a low drain voltage. As the degree of integration of devices increases, the total channel length needs to be reduced. However, a reduction in a channel length causes various problems due to a short channel effect. For example, when a channel length is reduced to approximately 50 nm or less, the size of a depletion layer increases, thereby the density of charge carriers changes and current flowing between a gate and a channel increases.

To solve these problems, a study has been made on field effect transistors using a Mott-Hubbard insulator as a channel material, the Mott-Hubbard insulator undergoing a Hubbard's continuous metal-insulator transition, that is, a second-order phase transition. A Hubbard's continuous metal-insulator transition was explained by J. Hubbard, in “Proc. Roy. Sci. (London) A276, 238 (1963), A281, 40-1 (1963),” and a transistor using the Hubbard's continuous metal-insulator transition was disclosed by D. M. Newns, J. A. Misewich, C. C. Tsuei, A, Gupta, B. A. Scott, and A. Schrott, in “Appl. Phys. Left. 73, 780 (1998).” Transistors using a Hubbard's continuous metal-insulator transition are called Mott-Hubbard field effect transistors or Mott field effect transistors. Mott-Hubbard field effect transistors perform on/off operation according to a metal-insulator transition. In contrast to MOSFETs, Mott-Hubbard field effect transistors do not include any depletion layer, and accordingly, can drastically improve the degree of integration thereof. In addition, Mott-Hubbard field effect transistors are said to provide a higher speed switching function than MOSFETs.

On the other hand, Mott-Hubbard field effect transistors use a Mott-Hubbard insulator as a channel material. The insulator has a metallic structure which is one electron per atom The non-uniformity results in large leakage current, and accordingly, the transistors cannot achieve high current amplification at a low gate voltage and a low source-drain voltage. For example, a Mott-Hubbard insulator, such as Y₁₋ₓPrₓBa₂Cu₃O_{7-d} (YPBCO), includes an element Cu with high conductivity.

### DISCLOSURE OF THE INVENTION

The present invention provides a field effect transistor using an insulator-semiconductor transition material layer as a channel material to achieve high current amplification at a low gate voltage and a low source-drain voltage.

The present invention also provides a method of manufacturing the field effect transistor.

In accordance with an aspect of the present invention, there is provided a field effect transistor comprising: an insulator-semiconductor transition material layer which selectively provides a first state in which charged holes are not introduced to a surface of the insulator-semiconductor transition material layer when a gate field is not applied and a second state in which a large number of charged holes are introduced to the surface of the insulator-semiconductor transition material layer when a negative field is applied to form a conductive channel; a gate insulating layer formed on the insulator-semiconductor transition material layer; a gate electrode formed on the gate insulating layer for applying a negative field of a predetermined intensity to the insulator-semiconductor transition material layer; and a source electrode and a drain electrode facing each other at both sides of the insulator-semiconductor transition material layer to move charge carriers through the conductive channel while the insulator-semiconductor material layer is in the second state.

The insulator-semiconductor transition material layer may be disposed on a silicon substrate, a silicon-on-insulator substrate, or a sapphire substrate.

The insulator-semiconductor transition material layer may be disposed on a silicon substrate, a silicon-on-insulator substrate, or a sapphire substrate.

The insulator-semiconductor transition material layer may be a vanadium dioxide (VO₂), V₂O₃, V₂O₅ thin films.

The insulator-semiconductor transition material layer may be an alkali-tetracyanoquinodimethane (TCNQ) thin film which is selected from the group consisting of Na-TCNQ, K-TCNQ, Rb-TCNQ, and Cs-TCNQ.

The gate insulating layer may be a dielectric layer selected from the group consisting of Ba_{0.5}Sr_{0.5}TiO₃, Pb₁₋ₓZrₓTiO₃ (0≦x≦0.5), Ta₂O₃, Si₃N₄, and SiO₂.

The source electrode, the drain electrode, and the gate electrode may be gold/chromium (Au/Cr) electrodes.

In accordance with another aspect of the present invention, there is provided a method of manufacturing a field effect transistor, comprising: forming an insulator-semiconductor transition material layer on a substrate to selectively provide a first state in which charged holes are not introduced to a surface of the insulator-semiconductor transition material layer when a field is not applied and a second state in which a large number of charged holes are introduced to the surface of the insulator-semiconductor transition material layer when a negative field is applied to form a conductive channel; forming a source electrode and a drain electrode to cover some portions at both sides of the insulator-semiconductor transition material layer; forming an insulating layer on the substrate, the source electrode, the drain electrode, and the insulator-semiconductor transition material layer; and forming a gate electrode on the insulating layer.

The substrate may be a single crystal silicon substrate, a silicon-on-insulator substrate, or a sapphire substrate.

The insulator-semiconductor transition material layer may be a vanadium dioxide thin film.

The insulator-semiconductor transition material layer may be an alkali-tetracyanoquinodimethane thin film.

The method may further comprise patterning the insulator-semiconductor transition material layer to have an area from several tens of nm² to several μm².

The patterning may be performed using a photolithography process and a radio frequency (RF)-ion milling process.

The source electrode, the drain electrode, and the gate electrode may be formed using a lift-off process.

### BRIEF DESCRIPTION OF THE DRAWINGS

FIG. 1 is a graph illustrating changes with temperature in a resistance of a channel material of a field effect transistor according to the present invention;

FIG. 2 is a graph illustrating Hall effect measurement results of the field effect transistor according to the present invention. Minus (−) means that carriers are holes;

FIG. 3 is a diagram illustrating a layout of a field effect transistor according to the present invention;

FIG. 4 is a cross-sectional view taken along the line II-II′ of the field effect transistor shown in FIG. 3;

FIG. 5 is an enlarged view of a portion “A” of the field effect transistor shown in FIG. 3; and

FIG. 6 is a graph illustrating operational characteristics of the field effect transistor shown in FIG. 3.

110: Al₂O₃ substrate, 120: VO₂ film, 130: Source Au/Cr electrode, 140: Drain Au/Cr electrode, 160: Gate Au/Cr electrode, 150: dielectric gate-insulator layer

### BEST MODE FOR CARRYING OUT THE INVENTION

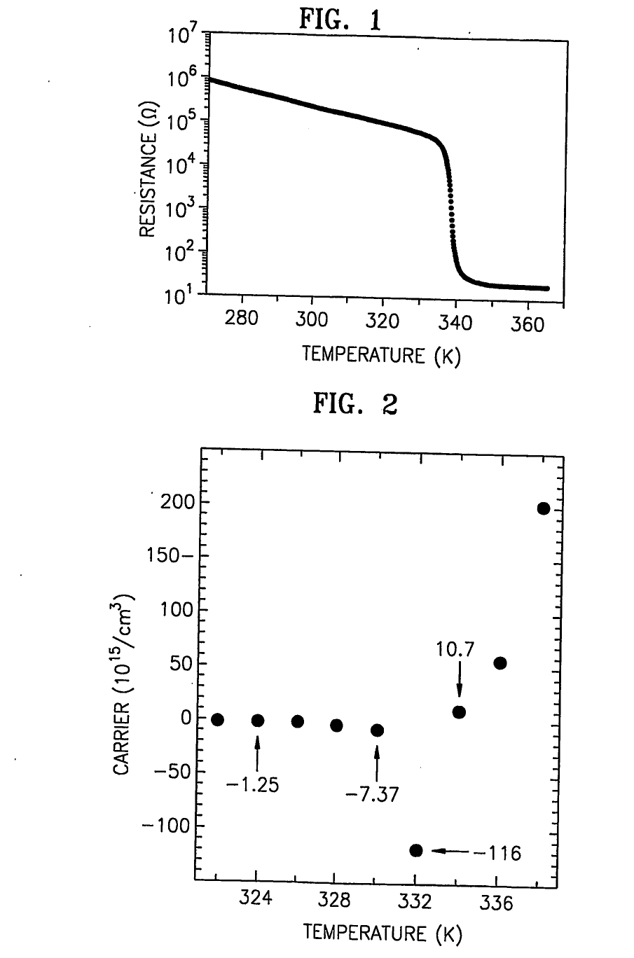

FIG. 1 is a graph illustrating changes with temperature in a resistance of a channel material of a field effect transistor according to the present invention.

Referring to FIG. 1, a representative example of an insulator-semiconductor transition material layer used as a channel material of a field effect transistor is a vanadium dioxide (VO₂) thin film. For example, a VO₂ thin film is a Mott-Brinkman-Rice insulator. Thus, resistance of the VO₂ thin film decreases logarithmically until temperature increases to approximately 330K. However, when the temperature reaches approximately 340K, a resistance of the VO₂ thin film sharply decreases, thereby causing a phase transition to metal. Although such a transition does not occur naturally at a normal temperature, the phase transition can occur at a normal temperature under specific conditions, that is, when predetermined potentials are applied to a surface of the VO₂ thin film and charged holes are injected into the VO₂ thin film. To use this physical insulator-metal transition phenomenon, the charged holes should be injected into the VO₂ thin film in a state where a relatively high voltage is applied between a drain and a source. The field effect transistor according to the present invention does not use the insulator-metal transition phenomenon. According to the field effect transistor of the present invention, even though a relatively low voltage is applied between the source and the drain, a negative field is formed on the surface of the VO₂ thin film to cause current to flow between the drain and the source.

FIG. 2 is a graph illustrating Hall effect measurement results of the VO₂ thin film for the field effect transistor according to the present invention. In FIG. 2, a symbol “−” represents a hole.

As shown in FIG. 2, Hall effect measurement results show that electrons of about 10.7×10¹⁵/cm³ are present within the VO₂ thin film at a temperature of about 332K, and the amount of electrons sharply increases as temperature increases. As previously explained, this is a theoretical base for explaining the insulator-metal transition of the VO₂ thin film. In the meantime, holes of about 1.16×10¹⁷/cm³ are present at a temperature of about 332K and holes of about 7.37×10¹⁵/cm³ are present at a temperature of about 330K. As the temperature decreases, the number of holes decreases gradually. Finally, holes of about 1.25×10¹⁵/cm³ are present at a temperature of about 324K. Differently from electrons, the number of holes induced by a gate field increases as the number of holes measured by Hall effect decreases due to charge conservation. That is, as temperature decreases, a larger number of holes are confined in a predetermined quantum well.

Accordingly, a good conductive state can be attained through induction of the large number of holes confined in the quantum well even upon application of a very low field. An insulator-semiconductor transition material has these characteristics. That is, the insulator-semiconductor transition material has such characteristics that it can maintain an insulation state when a field is not formed, whereas it can make a conductive channel using induced holes when a negative field is formed. Examples of the insulator-semiconductor transition material include an alkali-tetracyanoquinodimethan (TCNQ) material, besides the VO2 thin film. The alkali-TCNQ material may be selected from the group consisting of Na-TCNQ, K-TCNQ, Rb-TCNQ, and Cs-TCNQ.

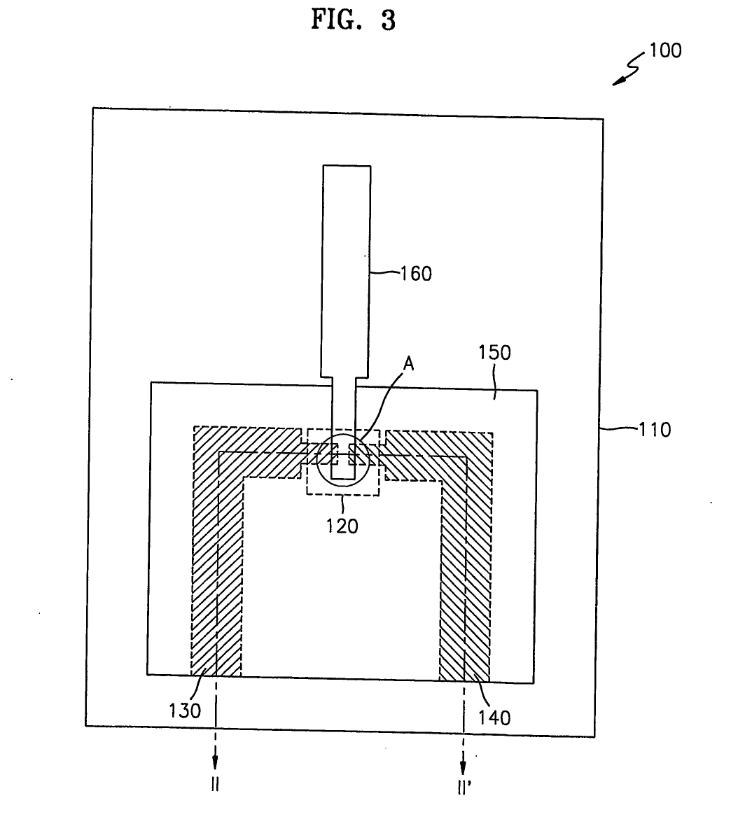

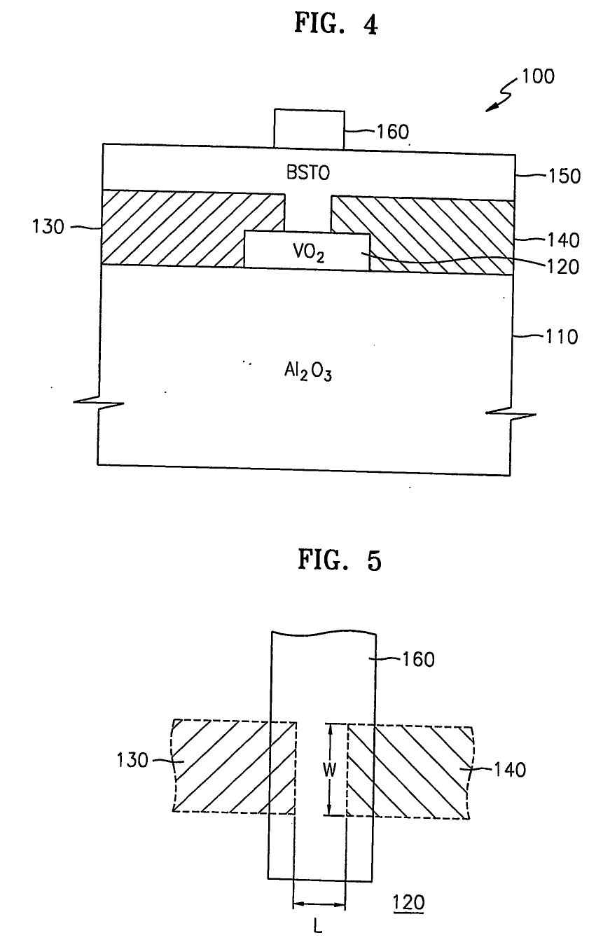

FIG. 3 is diagram illustrating a layout of a field effect transistor using an insulator-semiconductor transition material layer as a channel material. FIG. 4 is a cross-sectional view taken along the line II-II′ of the field effect transistor shown in FIG. 3. FIG. 5 is an enlarged plan view of a portion “A” of the field effect transistor shown in FIG. 3.

Referring to FIGS. 3 through 5, a VO₂ thin film 120 having a thickness of about 700-1000 Å and having a pattern with an area of several μm² is disposed on a single crystal sapphire (Al₂O₃) substrate 110. The VO₂ thin film 120 is an insulator-semiconductor transition material layer. Other insulator-semiconductor transition material layers can be used, instead of the VO₂ thin film 120. While the present embodiment employs the single crystal sapphire substrate 110 which provides suitable deposition conditions for growth of the VO₂ thin film 120, the present invention is not limited thereto. For example, a single crystal silicon (Si) substrate, or a silicon-on-insulator (SOI) substrate can be used, if necessary.

A first gold/chromium (Au/Cr) electrode 130 and a second Au/Cr electrode 140 are respectively formed as a source electrode and a drain electrode on some portions of the single crystal sapphire substrate 110 and the VO₂ thin film 120. The first Au/Cr electrode 130 is adhered to some portions at a left side of the VO₂ thin film 120. The second Au/Cr electrode 140 is adhered to some portions of a right side of the VO₂ thin film 120. The first Au/Cr electrode 130 and the second Au/Cr electrode 140 are spaced from each other by a channel length L and disposed on the VO₂ thin film 120 to face each other. As shown in FIG. 5, a distance between the first Au/Cr electrode 130 and the second Au/Cr electrode 140, that is, the length L of a channel, is approximately 3 μm, and a width W of the channel is approximately 50 μm. While the Au/Cr metal thin films are used as the source electrode and the drain electrode in the present embodiment, a Cr film in the Au/Cr double metal thin film functions as a buffer layer for good adhesion between the single crystal sapphire substrate 110 and an Au film, has a thickness of about 50 nm.

A gate insulating layer 150 is formed on the first and second Au/Cr electrodes 130 and 140 and the square VO₂ thin film 120 and on some portions of the sapphire substrate 110, leaving two electrode pads as shown in FIG. 3. While a Ba_{0.5}Sr_{0.5}TiO₃ (BSTO) dielectric layer having a dielectric constant of about 43 can be used as the gate insulating layer 150, the gate insulating layer 150 is not limited to the BSTO dielectric layer. Other dielectric layers than the BSTO dielectric layer, for example, Pb₁₋ₓZrₓTiO₃ (0≦x≦0.5) and Ta₂O₃ having a high dielectric constant, or Si₃N₄ and SiO₂ having general insulation property can be used as the gate insulating layer 150. A third Au/Cr electrode 160 is formed as a gate electrode on the gate insulating layer 150.

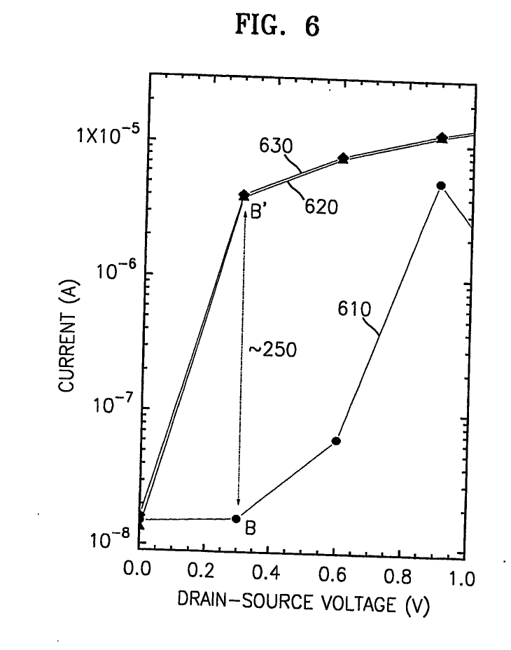

Operation and operational characteristics of the field effect transistor using the VO₂ thin film as a channel material will be explained with reference to a graph in FIG. 6.

As shown in FIG. 6, current is considerably different between a case 610 where a bias is not applied to the gate electrode 160 and cases 620 and 630 where a negative bias is applied to the gate electrode 160, at a low drain-source voltage. For example, in a state where a drain-source voltage is approximately 0.3V, when a bias is not applied to the gate electrode 160, current flowing between the source and the drain is so small that it can be ignored. This is because holes within the VO₂ thin film used as a channel material cannot exit from the quantum well. However, in a state where the drain-source voltage is approximately 0.3V, when a negative bias of −2V (620) or −10V (630) is applied to the gate electrode 160, current flowing between the source and the drain is 250 times larger than that when the bias is not applied to the gate electrode 160 (610). This is because when the negative bias of −2V or −10V is applied to the surface of the VO₂ thin film to induce holes within the quantum well to the surface of the VO₂ thin film, a conductive path is formed between the source and the drain.

A method of manufacturing the field effect transistor according to the present invention will be explained with reference to FIGS. 3 and 4.

First, the VO₂ thin film 120 is formed on the single crystal sapphire substrate 110 to have a thickness of about 700-1000 Å. A photoresist layer (not shown) is coated on the VO₂ thin film 120 using a spin-coater, and the VO₂ thin film 120 is patterned through a photolithography process using a Cr-mask and an etching process. A radio frequency (RF)-ion milling process can be used as the etching process. The VO₂ thin film 120 is patterned to have a square area of several μm².

Next, an Au/Cr layer is formed on the surface of the single crystal sapphire substrate 110, from which some portions of the VO₂ thin film are removed, and the square VO₂ thin film 120 to have a thickness of about 200 nm. The first Au/Cr electrode 130 and the second Au/Cr electrode 140 are formed to cover some portions at right and left sides of the VO₂ thin film 120 through a general lift-off process. When some portions of the Au/Cr layer are removed through the lift-off process, care should be taken so as for a channel to have a length of 3 μm and a width of 50 μm. The channel length and width can vary, if necessary.

Next, the gate insulating layer 150 is formed on the exposed surfaces of the single crystal sapphire substrate 110, the first Au/Cr electrode 130, the second Au/Cr electrode 140, and the VO₂ thin film 120. Next, the gate insulating layer 150 is patterned to prominently show pads of the first electrode 130 and the second electrode 140. The third Au/Cr electrode 160 is formed as a gate electrode on the gate insulating layer 150. The third Au/Cr electrode 160 is formed in the same manner as the first and second Au/Cr electrodes 130 and 140.

As described above, a field effect transistor according to the present invention uses an insulator-semiconductor transition material thin film as a channel material, in contrast to the conventional art which employs a pn-junction semiconductor structure. Therefore, the field effect transistor of the present invention has an advantage in that it does not suffer problems caused due to a short channel effect, and accordingly, can improve the degree of integration thereof and a switching speed. The field effect transistor has another advantage in that it can provide an insulation state or a conductive state according to whether a negative voltage is applied to a gate electrode in a state where a relatively low bias is applied between a drain and a source. In particular, current flowing in the conductive state can be about 250 times more than that flowing in the insulation state.

While the present invention has been particularly shown and described with reference to exemplary embodiments thereof, it will be understood by those of ordinary skill in the art that various changes in form and details may be made therein without departing from the spirit and scope of the present invention as defined by the following claims.

What is claimed is:

1. A field effect transistor comprising:
an insulator-semiconductor transition material layer which selectively provides a first state in which charged holes are not introduced to a surface of the insulator-semiconductor transition material layer when a gate field is not applied and a second state in which a large number of charged holes are introduced to the surface of the insulator-semiconductor transition material layer when a negative field is applied to form a conductive channel;
a gate insulating layer formed on the insulator-semiconductor transition material layer;
a gate electrode formed on the gate insulating layer for applying a negative field of a predetermined intensity to the insulator-semiconductor transition material layer; and
a source electrode and a drain electrode facing each other at both sides of the insulator-semiconductor transition material layer to move charge carriers through the conductive channel while the insulator-semiconductor material layer is in the second state.

2. The field effect transistor of claim 1, wherein the insulator-semiconductor transition material layer is disposed on a silicon substrate, a silicon-on-insulator substrate, or a sapphire substrate.

3. The field effect transistor of claim 1, wherein the insulator-semiconductor transition material layer is a vanadium dioxide (VO₂), V₂O₃, V₂O₅ thin films.

4. The field effect transistor of claim 1, wherein the insulator-semiconductor transition material layer is an alkali-tetracyanoquinodimethane thin film which is selected from the group consisting of Na-TCNQ, K-TCNQ, Rb-TCNQ, and Cs-TCNQ.

5. The field effect transistor of claim 1, wherein the gate insulating layer is a dielectric layer selected from the group consisting of Ba_{0.5}Sr_{0.5}TiO₃, Pb₁₋ₓZrₓTiO₃ (0≦x≦0.5), Ta₂O₃, Si₃N₄, and SiO₂.

6. The field effect transistor of claim 1, wherein the source electrode, the drain electrode, and the gate electrode are gold/chromium electrodes.

7. A method of manufactunng a field effect transistor, comprising:
forming an insulator-semiconductor transition material layer on a substrate to selectively provide a first state in which holes are not introduced to a surface of the insulator-semiconductor transition material layer when a field is not applied and a second state in which a large number of holes are introduced to the surface of the insulator-semiconductor transition material layer when a negative field is applied to form a conductive channel;
forming a source electrode and a drain electrode to cover some portions at both sides of the insulator-semiconductor transition material layer;
forming an insulating layer on the substrate, the source electrode, the drain electrode, and the insulator-semiconductor transition material layer; and
forming a gate electrode on the insulating layer.

8. The method of claim 7, wherein the insulator-semiconductor transition material layer is a vanadium dioxide thin film.

9. The method of claim 7, wherein the insulator-semiconductor transition material layer is an alkali-tetracyanoquinodimethane thin film which is selected from the group consisting of Na-TCNQ, K-TCNQ, Rb-TCNQ, and Cs-TCNQ.

10. The method of claim 7, further comprising patterning the insulator-semiconductor transition material layer to have an area from several tens of nm² to several μm².

11. The method of claim 10, wherein the patterning is performed using a photolithography process and a radio frequency-ion milling process.

12. The method of claim 7, wherein the source electrode, the drain electrode, and the gate electrode are formed using a lift-off process.
